(19) United States
(12) Patent Application Publication
(10) Pub. No.: US 2025/0148158 A1
(43) Pub. Date: May 8, 2025

(54) ENTRY/EXIT PATH-BASED SIZE AND PROPORTION OPTIMIZER

(71) Applicant: GM Global Technology Operations LLC, Detroit, MI (US)

(72) Inventors: Robert Alan Dziurda, Waterford, MI (US); Joseph F. Szczerba, Grand Blanc, MI (US); Christopher J. Kavanagh, Washington Township, MI (US); Thomas J. Kraemer, Macomb, MI (US); Roy J. Mathieu, Rochester Hills, MI (US); Jennifer A. Hullinger, Detroit, MI (US); Tracey A. Wilt, Washington Twp., MI (US); Anthony A. Bosco, Macomb Twp., MI (US); Maureen Elizabeth August, Gross Pointe Woods, MI (US)

(21) Appl. No.: 18/503,659

(22) Filed: Nov. 7, 2023

(51) Int. Cl. G06F 30/20; G06F 30/15

(52) U.S. Cl. CPC G06F 30/20; G06F 30/15

(57) ABSTRACT

A method for analyzing a vehicle user entry and egress into a vehicle includes receiving vehicle user data and receiving vehicle data. The vehicle data includes vehicle dimensions. The method further includes determining a three-dimensional path to enter and egress the vehicle using the vehicle user data and the vehicle data, determining a user satisfaction score of the three-dimensional path to enter and egress the vehicle, comparing the user satisfaction score with a predetermined score threshold to determine whether the user satisfaction score is greater than the predetermined score threshold; and virtually updating the vehicle dimensions until the user satisfaction score is greater than the predetermined score threshold in response to determining that the user satisfaction score is not greater than the predetermined score threshold.

### INTRODUCTION

The present disclosure relates to an entry/exit path-based size and optimizer for vehicles.

This introduction generally presents the context of the disclosure. Work of the presently named inventors, to the extent it is described in this introduction, as well as aspects of the description that may not otherwise qualify as prior art at the time of filing, are neither expressly nor impliedly admitted as prior art against this disclosure. Vehicle usually carry passengers from one location to another. Thus, vehicle users enter and exit the vehicle. It is therefore desirable to optimize the entry and egress of vehicle users to the vehicle.

### SUMMARY

The present disclosure describes a method for analyzing a vehicle user entry and egress into a vehicle. The method includes receiving vehicle user data and receiving vehicle data. The vehicle data includes vehicle dimensions. The method includes determining a three-dimensional path to enter and egress the vehicle using the vehicle user data and the vehicle data and determining a user satisfaction score of the three-dimensional path to enter and egress the vehicle comparing the user satisfaction score with a predetermined score threshold to determine whether the user satisfaction score is greater than the predetermined score threshold. Further, the method includes virtually updating the vehicle dimensions until the user satisfaction score is greater than the predetermined score threshold in response to determining that the user satisfaction score is not greater than the predetermined score threshold. Other embodiments of this aspect include corresponding computer systems, apparatus, and computer programs recorded on one or more computer storage devices, each configured to perform the actions of the methods. The method described in this paragraph improves vehicle technology by taking into account the particular user characteristics, such as the musculoskeletal ability of the user when the user enters or exits the vehicle, in selecting the dimensions of a vehicle.

Implementations may include one or more of the following features. The vehicle user data may include a user segment. The user segment includes able user, elderly user, corpulent user, disabled user, and user region. The vehicle data includes vehicle dimensions. The vehicle dimensions include the rocker height, roof height, door opening width, and stepover. The contextual data includes information about weather, incline of the vehicle, the clothing of a vehicle user, and whether the vehicle user is loading objects into the vehicle. The method may include determining the musculoskeletal ability of the vehicle user based on the user segment. The user satisfaction score is based on the musculoskeletal ability of the vehicle user. The method may include generating vehicle dimensional sensitivity scores for each of the vehicle dimensions. Implementations of the described techniques may include hardware, a method or process, or computer software on a computer-accessible medium.

The present disclosure also describes a system for analyzing a vehicle user entry and egress into a vehicle. The system includes sensors and a controller in communication with the sensors. The controller includes a processor and a non-transitory computer-readable medium and is programmed to execute the method described above.

The present disclosure further describes a tangible, non-transitory, machine-readable medium, comprising machine-readable instructions, that when executed by a processor, cause the processor to execute the method described above.

Further areas of applicability of the present disclosure will become apparent from the detailed description provided below. It should be understood that the detailed description and specific examples are intended for purposes of illustration only and are not intended to limit the scope of the disclosure.

The above features and advantages, and other features and advantages, of the presently disclosed system and method are readily apparent from the detailed description, including the claims, and exemplary embodiments when taken in connection with the accompanying drawings.

### BRIEF DESCRIPTION OF THE DRAWINGS

The present disclosure will become more fully understood from the detailed description and the accompanying drawings, wherein:

FIG. 1 is a block diagram depicting a system for analyzing a vehicle user entry and egress into a vehicle.

FIG. 2 is a schematic perspective view of a vehicle user entering a vehicle.

FIG. 3 is a flowchart of a method for analyzing a vehicle user entry and egress into a vehicle.

### DETAILED DESCRIPTION

Reference will now be made in detail to several examples of the disclosure that are illustrated in accompanying drawings. Whenever possible, the same or similar reference numerals are used in the drawings and the description to refer to the same or like parts or steps.

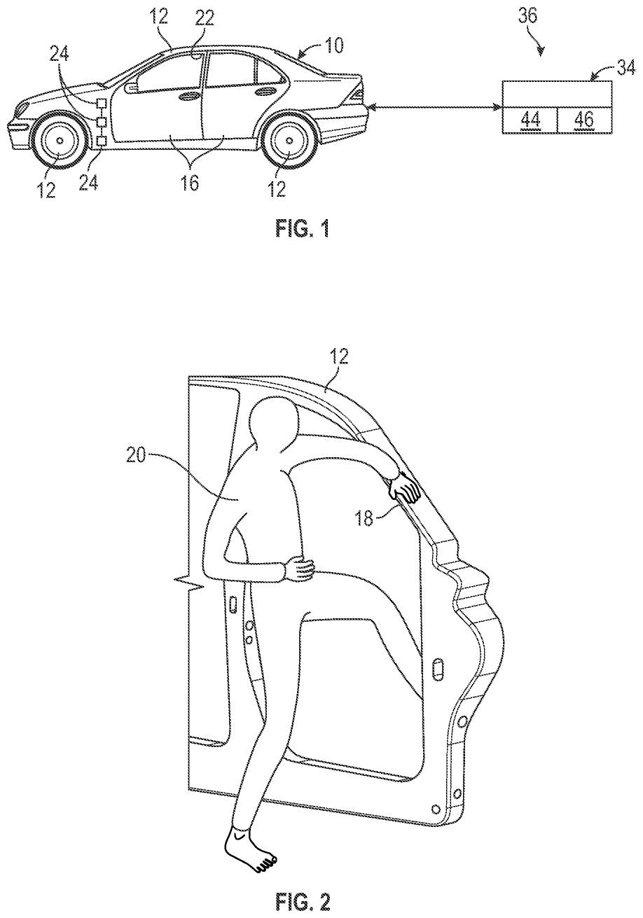

With reference to FIGS. 1 and 2, a host vehicle 10 includes a body 12 and a plurality of wheels 14 coupled to the body. In addition to the wheels 14, the vehicle 10 includes one or more doors 16 movably coupled to the body 12. The doors 16 are movable relative to the body 12 between an open position and a closed position. In the open position, the door 16 reveals an opening 18 into a passenger compartment 22 of the vehicle 10, thereby allowing the vehicle user 20 to enter or exit the vehicle 10.

The vehicle 10 includes one or more sensors 24 that sensor that sense observable conditions of the exterior environment and/or the interior environment of the host vehicle 10. At least one of the sensors 24 are capable of observing the entry and egress of the vehicle user 20 into or out of the vehicle 10. As non-limiting examples, the sensors 24 may include one or more cameras, one or more light detection and ranging (LIDAR) sensors, one or more proximity sensors, one or more cameras, one or more three-dimensional (3D) depth sensor, one or more ultrasonic sensors, one or more thermal imaging sensors, and/or other sensors. Each sensor 24 is configured to generate a signal that is indicative of the sensed observable conditions (i.e., sensor data) of the exterior environment and/or the interior environment of the vehicle 10.

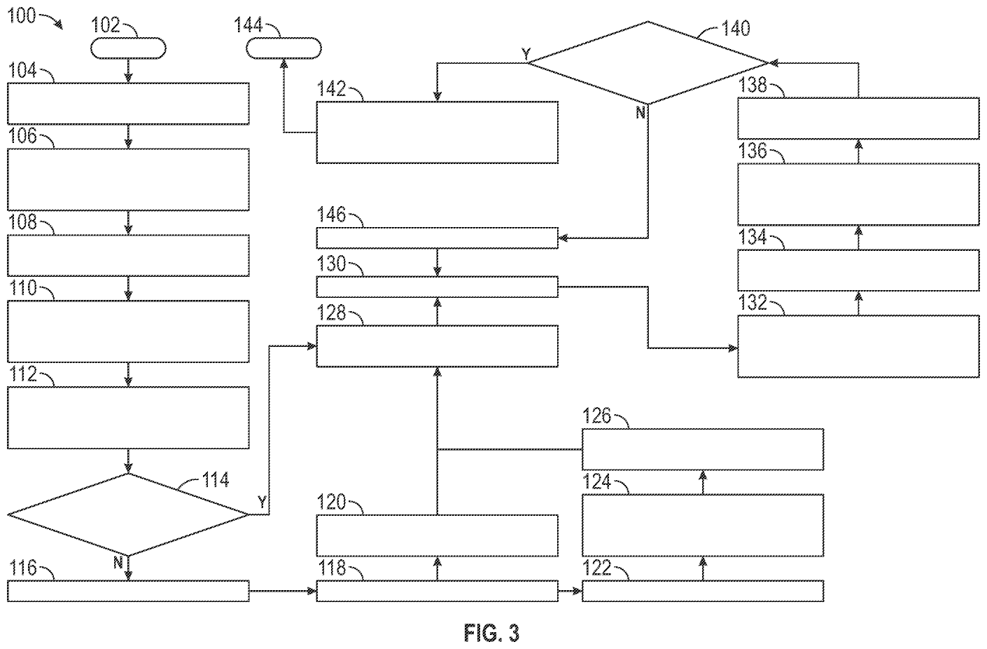

The vehicle 10 and therefore the vehicle sensors 24 are in communication with a controller 34. The controller 34 includes at least one processor 44 and a non-transitory computer readable storage device or media 46. The processor 44 may be a custom made or commercially available processor, a central processing unit (CPU), a graphics processing unit (GPU), an auxiliary processor among several processors associated with the controller 34, a semiconductor-based microprocessor (in the form of a microchip or chip set), a macroprocessor, a combination thereof, or generally a device for executing instructions. The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 34 in controlling the host vehicle 10. The controller 34 may be programmed to execute a method 100 (FIG. 3) as described in detail below.

The instructions may include one or more reroute programs, each of which comprises an ordered listing of executable instructions for implementing logical functions. The instructions, when executed by the processor 44, receive and process signals from the sensors 24, perform logic, calculations, methods and/or algorithms. Although a single controller 34 is shown in FIG. 1, a plurality of controllers 34 may be included that communicate over a suitable communication medium or a combination of communication mediums and that cooperate to process the sensor signals, perform logic, calculations, methods, and/or algorithms, and generate control signals to automatically control features of the host vehicle 10. The controller 34 is part of a system 36 for analyzing the entry and egress of the vehicle user 20 into or out of the vehicle 10.

The system 36 is a size and proportion optimizer layered on top of a human digital model route prediction tool. The system 36 employs digital human modelling (DHM) based guidance for complex 3D system interaction. Further, the system 36 uses an optimizing algorithm built to vary input parameters to test numerous configurations to understand sensitivity across the vehicle geometry, the human anthropometry, and human ability. The system 36 uses joint angle based and biomechanical force-based approaches.

FIG. 3 is a flowchart of a method 100 for analyzing the entry and egress of the vehicle user 20 into or out of the vehicle 10. The method 100 begins at block 102. Then, the method 100 proceeds to block 104. At block 102, a vehicle row of interest (e.g., first row, second row, third row) is selected. Vehicles 10 may include one or more row of seats. It is therefore desirable to indicate which row of seats will be analyzed. Next, the method 100 continues to block 106. At block 106, the controller 34 receives vehicle user data, such as a user segment and the human anthropometry. As non-limiting examples, the user segment may be an able user, an elderly user, a corpulent user, a disabled user, and a user region, among others. The method 100 then continues to block 108. Next, the method 100 proceeds to block 108.

At block 108, the controller 34 receives the requirements for the overall user satisfaction score. The overall user satisfaction score may be a predetermined score threshold determined based in input requirements, such as comfort, ease of entry, and ease of egress. Then, the method 100 continues to block 110.

At block 110, the controller 34 receives other vehicle data, such as the vehicle dimensions. As non-limiting examples, the vehicle dimensions may include includes rocker height, roof height, door opening width, and stepover, etc. Then, the method 100 continues to block 112.

At block 112, the controller 34 receives contextual data. As a non-limiting example, the contextual data includes information about weather, incline of the vehicle, a clothing of a vehicle user, human-related inputs (e.g., clothing, accessories, etc.), environmental inputs (e.g., when/where/how, weather, use of device, etc.), accessories, equipment inputs, situational inputs (e.g., in space with no gravity), input boundary conditions (e.g., tight parking lots), urgency/speed of action (e.g., weather or other), vehicle entry on various grades, and whether the vehicle user 20 is loading objects into the vehicle 10. Then, the method 100 continues to block 114.

At block 114, the controller 34 determines whether the user entry/egress data is available. If the user entry/egress data is available, then the method 100 proceeds to block 128. If the user entry/egress data is not available, then the method 100 continues to block 116. At block 116, the controller 34 obtains the user data. The user data may be referred to as the vehicle user data and may include the user segment as discussed above. Then, the method 100 proceeds to block 118. At block 118, the vehicle user 20 enters the vehicle 10. After block 118, the method 100 continues to block 120 and 122.

At block 120, the user satisfactory scores are obtained. As a non-limiting example, the vehicle user 20 may input the user satisfactory score after entering or exiting the vehicle 10. After block 120, the method 100 proceeds to block 128, which will be discussed below. At block 122, the motion of the vehicle user 20 while entering or exiting the vehicle 10 is captured with the sensors 24 (e.g., cameras) of the vehicle 10. As discussed above, the sensors 24 may be cameras that capture images of the vehicle user 20 entering or exiting the vehicle 10. Then, the method 100 continues to block 124. At block 123, the controller 34 identifies user entry/egress interference points with the vehicle 10 using the sensor data generated by the sensors 24. In other words, the controller 33 identifies the vehicle locations where the vehicle user 20 contacted the vehicle 10 while entering or exiting the vehicle 10. Then, the method 100 continues to block 126. The controller 34 identifies the motion strategies of the vehicle user 20 while entering and/or exiting the vehicle 10 that avoids the vehicle user 20 contacting the vehicle 10 while entering or exiting the vehicle 10. Then, the method 100 continues to block 128.

At block 128, the user data is fed into a three-dimensional (3D) computer-aided design (CAD) manikin. Then, the method 100 continuous to block 130. At block the 3D CAD manikin develops a 3D digital model of the vehicle user 10 using the user data. The 3D CAD manikin may use machine learning (e.g., a deep neural network) to develop the digital model of the vehicle user 20 while entering and/or entering the vehicle 10. Next, the method 100 continues to block 132. At block 132, the 3D CAD manikin then simulates the entry and egress of the vehicle user 20 into and out of the vehicle 10 and identifies the entry and egress paths that are most favorable to the vehicle user 20. The most favorable entry and egress path for the vehicle user 20 depends, among other things, on the user data and the vehicle data, and the contextual data. For example, the most favorable entry and/or egress path for the vehicle user 20 may be a path that avoids contact between the vehicle user 20 and the vehicle 10. In the present disclosure, the term “entry path” means a path for the vehicle user 20 to enter the vehicle 10. The term “egress path” means a path for the vehicle user 20 to exit the vehicle 10. In summary, at block 132, a three-dimensional path for the vehicle user 20 to enter and/or egress the vehicle 10 is determined using the vehicle user data and the vehicle data. The 3C CAD manikin also generates vehicle dimensional sensitivity scores for each of the vehicle dimensions. The vehicle dimensional sensitivity scores are indicative of how much the vehicle dimension can be changed before causing interference (i.e., physical contact) between the vehicle user 20 and the vehicle 10 while the vehicle user 20 follows the selected entry and/or exit path for entering or exiting the vehicle 10. The method 100 then continues to block 134.

At block 132, the three-dimensional path for the vehicle user 20 to enter and/or egress the vehicle 10 is fed to a musculoskeletal model. Next, the method 100 continues to block 136. At block 136, the musculoskeletal ability of the vehicle user 20 is determined based on the user segment. The musculoskeletal model uses a kinematic analysis procedure of over-determined biomechanical systems, which is formulated as a weighted least-squares optimization problem that matches experimental and model marker positions. Thus, the musculoskeletal model uses machine learning (e.g., a deep neural network) to determine its output. As its output, the musculoskeletal model determines linear and angular displacements, velocities, accelerations for all body segments of the vehicle user while entering and/or exiting the vehicle 10 using the previously determined entry and/or egress path. Further, the musculoskeletal model may also determine the muscle length, activation, moment arm and force, joint reaction forces, the position of muscle origins/via points/insertions throughout the previously determined entry and/or egress path for the vehicle user 20 to enter and/or exit the vehicle 10. The method 100 then proceeds to block 138.

At block 138, an overall user satisfaction score of the three-dimensional path to enter and egress the vehicle 10 is determined based on the musculoskeletal model of the vehicle user 20 entering or exiting the vehicle 10 using the previously determined entry or egress path. Thus, the overall user satisfaction score is determined based on the musculoskeletal ability of the vehicle user 20. For instance, the overall user satisfaction score of the three-dimensional path to enter and egress the vehicle 10 may depend, among other things, on whether joint forces experienced by the vehicle user 20 when following the previously determined entry or egress path to enter or exit the vehicle 10 are greater than a predetermined force threshold. As another example, the overall user satisfaction score of the three-dimensional path to enter and egress the vehicle 10 may depend, among other things, on whether the linear and angular displacements, velocities, accelerations experienced by the vehicle user 20 when following the previously determined entry or egress path to enter or exit the vehicle 10 are greater than a respective threshold. Once the overall user satisfaction score of the three-dimensional path to enter and egress the vehicle 10 is determined, the method 100 proceeds to block 140.

At block 140, the overall user satisfaction score is compared with a predetermined score threshold to determine whether the user satisfaction score is greater than the predetermined score threshold. If the overall user satisfaction score is greater than the predetermined score threshold, then the method 100 continues to block 142. At block 142, the vehicle dimension and the vehicle dimensional sensitivity scores are recorded. Block 124 may also entail manufacturing the vehicle 10 with the recorded vehicle dimensions. Then, the method 100 continuous to block 144. At block 144, the method 100 ends.

At block 140, if the overall user satisfaction score is not greater than the predetermined score threshold, then the method 100 proceeds to block 146. At block 146, the vehicle dimensions are virtually updated and the method 100 returns to block 130. Thus, the vehicle dimensions are virtually updated in an iterative process (i.e., method 100) until the overall user satisfaction score is greater than the predetermined score threshold. At block 140, the system 36 may virtually produce vehicular configuration dimensions optimized around “not-to-exceed” parameters like muscle effort, forces on joints, and/or anthropomorphic variables. Further, the system 36 may produce virtual 3D entry/exit envelopes optimized around “not-to-exceed parameters like muscle effort, forces on joints, and/or anthropomorphic variables. Moreover, the system 36 may produce vehicle section geometry (e.g., raises roof, lower rocker, or increase couple, etc.) optimized around “not-to-exceed” parameters like muscle effort, forces on joints, and/or andromorphic variables. Further, the system 36i may output virtual morphed vehicle geometry/surfaces (e.g., raises roof, moves A-pillar, or increases wheelbase, etc.) optimized around “not-to-exceed” parameters like muscle effort, forces on joints, and/or andromorphic variables.

The end state may be defined using weighting, enabling Artificial Intelligence (AI), and better future suggestions. To do so, the following features may be used: spider charts to inform the optimizer what we want (e.g., narrow recommendations), teaching design, teaching aerodynamics, and enabling AI for individual designers (e.g., the individual designers may train the AI to help iterate designs around their style).

The system 34 and the method 100 may be used for the following applications: cargo loading; EV charging interface; child seat install or entry/egress/buckling; assembly of vehicles; scan any vehicle and compare to ability of person to guide modifications (e.g., cost/benefit optimizer), thereby new vehicles modified or new vehicle purchases recommendations may be made, planes; planes, trains, boats, RVs, and buses; public transport, military (e.g., gear, etc.); space (space suites, gloves, rocket packs, etc.); law enforcement; ride share accommodations; golf carts, recreational vehicles, etc.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the presently disclosed system and method that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

The drawings are in simplified form and are not to precise scale. For purposes of convenience and clarity only, directional terms such as top, bottom, left, right, up, over, above, below, beneath, rear, and front, may be used with respect to the drawings. These and similar directional terms are not to be construed to limit the scope of the disclosure in any manner.

Embodiments of the present disclosure are described herein. It is to be understood, however, that the disclosed embodiments are merely examples and other embodiments can take various and alternative forms. The figures are not necessarily to scale; some features could be exaggerated or minimized to display details of particular components. Therefore, specific structural and functional details disclosed herein are not to be interpreted as limiting, but merely as a representative basis for teaching one skilled in the art to variously employ the presently disclosed system and method. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Embodiments of the present disclosure may be described herein in terms of functional and/or logical block components and various processing steps. It should be appreciated that such block components may be realized by a number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present disclosure may be practiced in conjunction with a number of systems, and that the systems described herein are merely exemplary embodiments of the present disclosure.

For the sake of brevity, techniques related to signal processing, data fusion, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that alternative or additional functional relationships or physical connections may be present in an embodiment of the present disclosure.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A method for analyzing a vehicle user entry and egress into a vehicle, comprising:
receiving vehicle user data;
receiving vehicle data, wherein the vehicle data include vehicle dimensions;
determining a three-dimensional path to enter and exit the vehicle using the vehicle user data and the vehicle data;
determining a user satisfaction score of the three-dimensional path to enter and exit the vehicle;
comparing the user satisfaction score with a predetermined score threshold to determine whether the user satisfaction score is greater than the predetermined score threshold; and
in response to determining that the user satisfaction score is not greater than the predetermined score threshold, virtually updating the vehicle dimensions until the user satisfaction score is greater than the predetermined score threshold.

2. The method of claim 1, wherein the vehicle user data includes a user segment, and the user segment includes able user, elderly user, corpulent user, disabled user, and user region.

3. The method of claim 2, wherein the vehicle data includes vehicle dimensions, and the vehicle dimensions includes rocker height, roof height, door opening width, and stepover.

4. The method of claim 3, further comprising receiving contextual data, wherein the contextual data includes information about weather, incline of the vehicle, a clothing of a vehicle user, and whether the vehicle user is loading objects into the vehicle.

5. The method of claim 4, further comprising determining a musculoskeletal ability of the vehicle user based on the user segment.

6. The method of claim 5, wherein the user satisfaction score is based on the musculoskeletal ability of the vehicle user.

7. The method of claim 6, further comprising generating vehicle dimensional sensitivity scores for each of the vehicle dimensions.

8. A system for analyzing a vehicle user entry and egress into a vehicle, comprising:
a plurality of sensors;
a controller including a processor and a non-transitory computer-readable media, wherein the controller is in communication with the plurality of sensors, and the controller is programmed to:
receive vehicle user data;
receive vehicle data, wherein the vehicle data include vehicle dimensions;
determine a three-dimensional path to enter and exit the vehicle using the vehicle user data and the vehicle data;
determine a user satisfaction score of the three-dimensional path to enter and exit the vehicle;
compare the user satisfaction score with a predetermined score threshold to determine whether the user satisfaction score is greater than the predetermined score threshold; and
in response to determining that the user satisfaction score is not greater than the predetermined score threshold, virtually update the vehicle dimensions until the user satisfaction score is greater than the predetermined score threshold.

9. The system of claim 8, wherein the vehicle user data includes a user segment, and the user segment includes able user, elderly user, corpulent user, disabled user, and user region.

10. The system of claim 9, wherein the vehicle data includes vehicle dimensions, and the vehicle dimensions includes rocker height, roof height, door opening width, and stepover.

11. The system of claim 10, wherein the controller is programmed to receive contextual data, wherein the contextual data includes information about weather, incline of the vehicle, a clothing of a vehicle user, and whether the vehicle user is loading objects into the vehicle.

12. The system of claim 11, wherein the controller is programmed to determine a musculoskeletal ability of the vehicle user based on the user segment.

13. The system of claim 12, wherein the user satisfaction score is based on the musculoskeletal ability of the vehicle user.

14. The system of claim 13, further comprising generating vehicle dimensional sensitivity scores for each of the vehicle dimensions.

15. A tangible, non-transitory, machine-readable medium, comprising machine-readable instructions, that when executed by a processor, cause the processor to:
receive vehicle user data;
receive vehicle data, wherein the vehicle data include vehicle dimensions;
determine a three-dimensional path to enter and egress a vehicle using the vehicle user data and the vehicle data;
determine a user satisfaction score of the three-dimensional path to enter and exit the vehicle;
compare the user satisfaction score with a predetermined score threshold to determine whether the user satisfaction score is greater than the predetermined score threshold; and
in response to determining that the user satisfaction score is not greater than the predetermined score threshold, virtually update the vehicle dimensions until the user satisfaction score is greater than the predetermined score threshold.

16. The tangible, non-transitory, machine-readable medium of claim 15, wherein the vehicle user data includes a user segment, and the user segment includes able user, elderly user, corpulent user, disabled user, and user region.

17. The tangible, non-transitory, machine-readable medium of claim 16, wherein the vehicle data includes vehicle dimensions, and the vehicle dimensions includes rocker height, roof height, door opening width, and stepover.

18. The tangible, non-transitory, machine-readable medium of claim 16, wherein the tangible, non-transitory, machine-readable medium further comprising machine-readable instructions, that when executed by the processor, causes the processor to receive contextual data, wherein the contextual data includes information about weather, incline of the vehicle, a clothing of a vehicle user, and whether the vehicle user is loading objects into the vehicle.

19. The tangible, non-transitory, machine-readable medium of claim 16, wherein the tangible, non-transitory, machine-readable medium further comprising machine-readable instructions, that when executed by the processor, causes the processor to determine a musculoskeletal ability of a vehicle user based on the user segment.

20. The tangible, non-transitory, machine-readable medium of claim 19, wherein the user satisfaction score is based on the musculoskeletal ability of the vehicle user.
